(19) United States
(12) Patent Application Publication
(10) Pub. No.: US 2008/0212292 A1
(43) Pub. Date: Sep. 4, 2008

(54) ELECTRONIC DEVICE WITH WATERPROOF STRUCTURE AND FABRICATION METHOD THEREOF

(75) Inventors: Wen-Lung Yu, Taoyuan (TW); Yu-Tang Liu, Taoyuan (TW)

Correspondence Address: MADSON & AUSTIN, 15 WEST SOUTH TEMPLE, SUITE 900, SALT LAKE CITY, UT, 84101, US

(73) Assignee: Delta Electronics, Inc., Taoyuan Hsien (TW)

(21) Appl. No.: 11/751,775

(22) Filed: May 22, 2007

(30) Foreign Application Priority Data
Mar. 2, 2007 (TW) 096107284

(51) Int. Cl. H05K 1/18

(52) U.S. Cl. 361/748; 29/592.1

(57) ABSTRACT

An electronic device with a waterproof structure includes a housing structure, a printed circuit board and a protective layer. The housing structure includes a receptacle, a first opening and a second opening. The printed circuit board is disposed within the receptacle and includes plural electronic components and electrical trace patterns thereon. The protective layer is formed on at least a portion of the electronic components and the electrical trace patterns to protect the printed circuit board from moisture attack.

### FIELD OF THE INVENTION

The present invention relates to an electronic device, and more particularly to an electronic device with a waterproof structure. The present invention also relates to a method for fabricating such an electronic device.

### BACKGROUND OF THE INVENTION

With increasing integration of integrated circuits, electronic devices such as power adapters and power supply apparatuses are developed toward minimization. As the volume of the electronic device is decreased, the problem associated with heat dissipation becomes more serious. Take a power adapter for example. The conventional power adapter comprises an upper housing and a lower housing, which are made of plastic materials and cooperatively defines a receptacle for accommodating a printed circuit board. When the power adapter operates, the electronic components on the printed circuit board thereof may generate energy in the form of heat, which is readily accumulated within the receptacle and usually difficult to dissipate away. If the power adapter fails to transfer enough heat to ambient air, the elevated operating temperature may result in damage of the electronic components, a breakdown of the whole power adapter or reduced power conversion efficiency.

Referring to FIG. 1, a schematic cross-sectional view of a conventional power adapter having a heat-dissipating mechanism is illustrated. The power adapter 1 comprises an upper housing 11, a lower housing 12, a printed circuit board 13, a power input terminal (not shown) and a power output terminal 14. A receptacle is defined between the upper housing 11 and the lower housing 12 for accommodating the printed circuit board 13 therein. Many electronic components 131 and electrical trace patterns (not shown) are mounted on the printed circuit board 13. By the electronic components 131 and the electrical trace patterns, an input voltage from the external power source is converted into a regulated DC output voltage for powering an electronic product. In order to remove most heat generated from the electronic components 131, several heat sinks 132 are usually provided on the printed circuit board 13. In addition, some electronic components 131 are coupled to the heat sinks 132 by screwing or riveting connection, thereby facilitating heat dissipation.

The heat-dissipating mechanism of the power adapter 1 comprises conducting the heat generated from the electronic components 131 to the heat sinks 132, radiating the heat from the surfaces of the heat sinks 132 to the receptacle of the power adapter 1, transferring the heat from the receptacle to the upper housing 11 and the lower housing 12 through air, and afterwards performing heat-exchange with the surrounding of the power adapter 1. Since the power adapter 1 is developed toward minimization and designed to have higher power, the passive heat-dissipating mechanism described above is not satisfactory.

For enhancing heat-dissipating efficiency, the heat generated from the internal electronic components of the power adapter 1 should be actively dissipated away the power adapter 1. In order to be applied to diversified electronic devices such as network devices, communication devices, information devices and game consoles, the power adapter 1 should be operated under most operating statues and environments. For example, the housing of the power adapter 1 may have additional openings such that the space defined by the housing is communicated with external ambient air. Under this circumstance, the power adapter 1 fails to be operated in humid surroundings or outdoors due to the poor waterproof properties. If the power adapter 1 having the active heat-dissipating mechanism is used in the humid surroundings or outdoors, the electronic components may be damaged or shorted in case of contacting with water. Moreover, foreign matters (e.g. vermin) or dust may enter the inner space of the power adapter 1 through the openings. The foreign matters or dust may result in a continuity failure or damage of the printed circuit board, and thus the whole computer or power supply apparatus may be short-circuited or have a breakdown. As a consequence, the quality and the reliability of the power adapter 1 are impaired.

Referring to FIG. 2, a schematic cross-sectional view of a power adapter with a waterproof and heat-dissipating structure according to prior art is illustrated. The power adapter 2 of FIG. 2 comprises a housing structure 21, a fan 22, a first opening 23, a second opening 24, a spacing structure 25 and a printed circuit board 26. The housing structure 21 includes an upper housing 211 and a lower housing 212. The first opening 23 and the second opening 24 are arranged in the housing structure 21. The spacing structure 25 is disposed within the housing structure 21 for partitioning the space within the housing structure 21 into an airflow channel 27 and a receptacle 28. The spacing structure 25 is substantially a metallic plate. The airflow channel 27 is formed between the inner surface of the housing structure 21 and the spacing structure 25, and communicated with the first opening 23 and the second opening 24. The fan 22 is disposed in the airflow channel 27. By means of the fan 22, air is forced to flow into the airflow channel 27 through the first opening 23 and exhausted through the second opening 24 so as to dissipate heat generated from the electronic components on the printed circuit board 26 in accordance with an active heat-dissipating mechanism. In addition, since the spacing structure 25 can separate the airflow channel 27 from the receptacle 28, moisture or liquid from the ambient air will no longer attack the printed circuit board 26 so as to achieve waterproof and heat-dissipating objects.

Although the waterproof and heat-dissipating structure is effective for preventing water from entering the housing structure and removing heat, there are still some drawbacks. For example, the waterproof and heat-dissipating structure is complicated and thus not cost-effective. In addition, since a poor thermally-conductive medium (i.e. air) exists between the spacing structure 25 and the electronic components 261 and/or the heat sinks 262, the heat-dissipating efficiency of such a heat-dissipating mechanism is not satisfied.

In views of the above-described disadvantages resulted from the conventional method, the applicant keeps on carving unflaggingly to develop an electronic device with a waterproof structure according to the present invention through wholehearted experience and research.

### SUMMARY OF THE INVENTION

It is an object of the present invention to provide an electronic device with a waterproof structure for preventing water or foreign matters from entering the housing structure and facilitating heat dissipation in an active heat-dissipating mechanism.

Another object of the present invention provides an electronic device with a waterproof structure, in which a protective layer is formed on at least a portion of the electronic components and the electrical trace patterns on the printed circuit board to facilitate dissipating heat and withstanding vibration, impact or pressure.

Another object of the present invention provides a process of fabricating an electronic device with a waterproof structure in a simple and cost-effective manner.

In accordance with an aspect of the present invention, there is provided an electronic device with a waterproof structure. The electronic device includes a housing structure, a printed circuit board and a protective layer. The housing structure includes a receptacle, a first opening and a second opening. The printed circuit board is disposed within the receptacle and includes plural electronic components and electrical trace patterns thereon. The protective layer is formed on at least a portion of the electronic components and the electrical trace patterns to protect the printed circuit board from moisture attack.

In accordance with another aspect of the present invention, there is provided a process for fabricating an electronic device with a waterproof structure. The process includes steps of (a) providing a printed circuit board, wherein plural electronic components and electrical trace patterns are mounted on the printed circuit board; (b) forming a protective layer on at least a portion of the electronic components and the electrical trace patterns, which are mounted on the printed circuit board; and (c) accommodating the printed circuit board within a receptacle of a housing structure, thereby fabricating the electronic device.

The above contents of the present invention will become more readily apparent to those ordinarily skilled in the art after reviewing the following detailed description and accompanying drawings, in which:

### BRIEF DESCRIPTION OF THE DRAWINGS

FIG. 1 is a schematic cross-sectional view of a conventional power adapter having a heat-dissipating mechanism;

FIG. 2 is a schematic cross-sectional view of a power adapter with a waterproof and heat-dissipating structure according to prior art;

FIG. 3 is a schematic cross-sectional view of an electronic device with a waterproof structure according to a preferred embodiment of the present invention;

FIGS. 4(a) and 4(b) are schematic cross-sectional views of an electronic device with a waterproof structure according to a second preferred embodiment of the present invention; and

FIG. 5 is a flowchart of the process for fabricating an electronic device with a waterproof structure according to a preferred embodiment of the present invention.

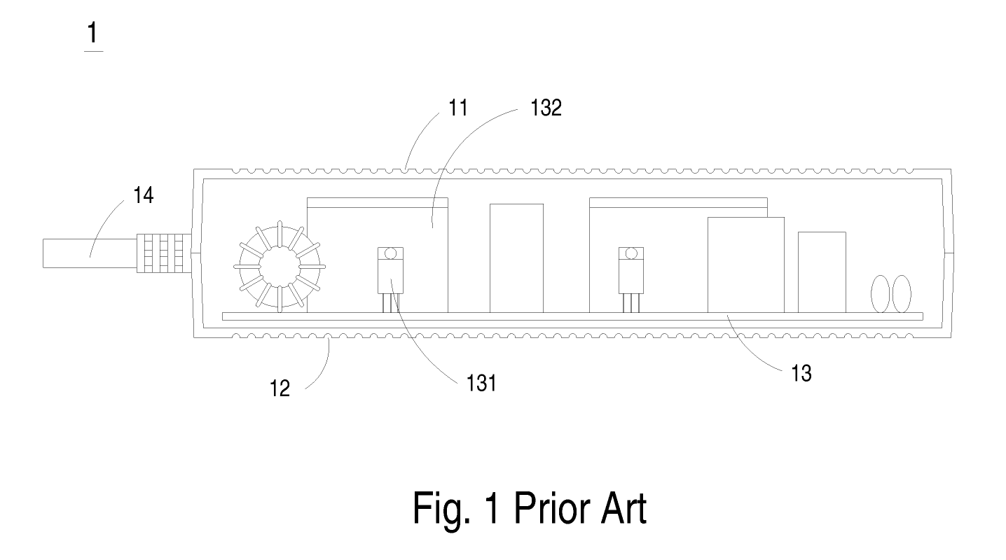

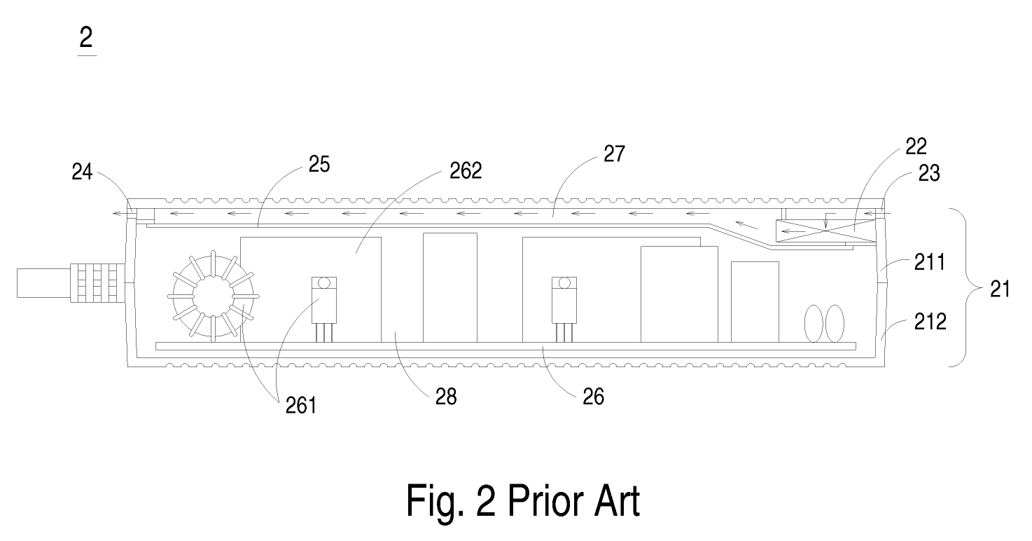

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

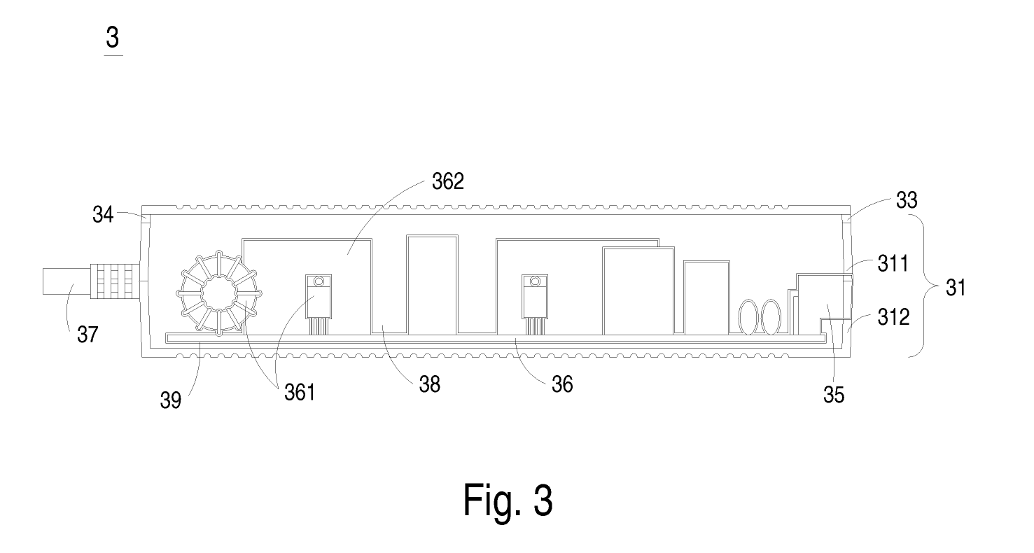

Referring to FIG. 3, a schematic cross-sectional view of an electronic device with a waterproof structure according to a preferred embodiment of the present invention is illustrated. The electronic device 3 is for example a power supply apparatus or a power adapter. The power adapter 3 comprises a housing structure 31, a first opening 33, a second opening 34, a power input member 35, a printed circuit board 36 and a power output member 37. The housing structure 31 includes an upper housing 311 and a lower housing 312. A receptacle 38 is defined between the upper housing 311 and the lower housing 312 for accommodating the printed circuit board 36 therein. The first opening 33 and the second opening 34 are arranged in the housing structure 31. Many electronic components 361, electrical trace patterns (not shown) and heat sinks 362 are mounted on the printed circuit board 36. By the electronic components 361 and the electrical trace patterns, an input voltage from the external power source is converted into a regulated DC output voltage for powering an electronic product. In accordance with a specific feature of the present invention, a protective layer 39 is formed on at least a portion of the electronic components 361 and the electrical trace patterns on the printed circuit board 36. The protective layer 39 is made of conformal coating material, and preferably transparent conformal coating material. The protective layer 39 is formed on the electronic components 361 and the electrical trace patterns by a dip coating, spin-coating or spraying process. The power input member 35 is for example a power socket. The power output member 37 is for example a power cable. The first opening 33 and the second opening 34 of the housing structure 31 may facilitate dissipating the heat to the surroundings. Since the electronic components 361, the electrical trace patterns and the printed circuit board 36 are protected by the protective layer 39, the adverse effects of water, liquid or foreign matters entering the receptacle 38 are minimized. As a consequence, the possibilities of causing short-circuit or damage of the electronic components 361, the electrical trace patterns and the printed circuit board 36 is largely reduced. Due to the protective layer 39, the electronic device 3 may be operated in most circumstances. Moreover, the protective layer 39 has additional functions of withstanding vibration, impact or pressure.

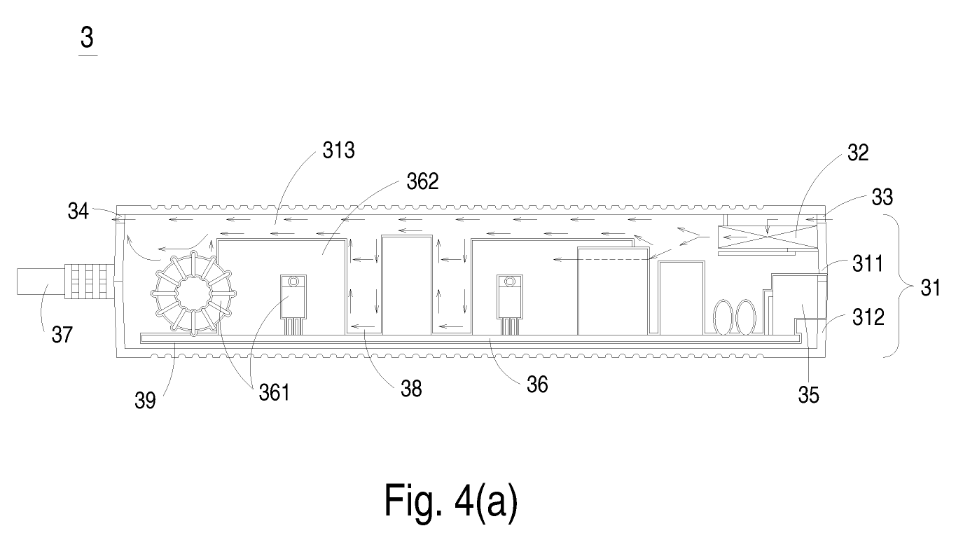

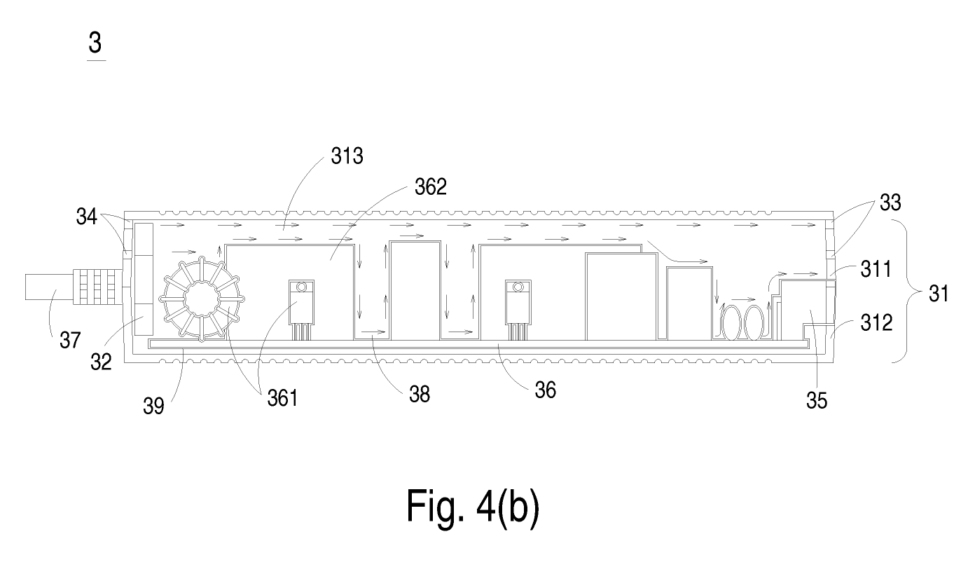

A further embodiment of an electronic device with a waterproof structure is illustrated in FIG. 4(a). The housing structure 31, the first opening 33, the second opening 34, the power input member 35, the printed circuit board 36 and the power output member 37 included therein are similar to those shown in FIG. 3, and are not redundantly described herein. In this embodiment, the electronic device 3 further includes a fan 32 such as a blower. The fan 32 is disposed within the housing structure 31 and adjacent to the first opening 33 or the second opening 34. When the fan 32 is actuated, an airflow channel 313 is formed between the first opening 33 and the second opening 34. In a case that the fan 32 is disposed adjacent to the first opening 33, air is forced to flow into the airflow channel 313 through the first opening 33 and exhausted through the second opening 34 so as to dissipate heat generated from the electronic components on the printed circuit board 36 in accordance with an active heat-dissipating mechanism. Whereas, in another case that the fan 32 is disposed adjacent to the second opening 34, air is forced to flow into the airflow channel 313 through the second opening 34 and exhausted through the first opening 33 so as to dissipate heat generated from the electronic components on the printed circuit board 36 in accordance with an active heat-dissipating mechanism. Since the electronic components 361, the electrical trace patterns and the printed circuit board 36 are protected by the protective layer 39, the adverse effects of water, liquid or foreign matters entering the receptacle 38 are minimized. Therefore, the waterproof structure of the present invention is capable of enhancing heat-dissipating efficiency and preventing from moisture attack.

A further embodiment of an electronic device with a waterproof structure is illustrated in FIG. 4(b). The housing structure 31, the first opening 33, the second opening 34, the power input member 35, the printed circuit board 36 and the power output member 37 included therein are similar to those shown in FIG. 3, and are not redundantly described herein. In this embodiment, the electronic device 3 further includes a fan 32 such as an axial-flow fan. The fan 32 is disposed within the housing structure 31 and adjacent to the second opening 34 or the first opening 33. When the fan 32 is actuated, an airflow channel 313 is formed between the first opening 33 and the second opening 34. In a case that the fan 32 is disposed adjacent to the second opening 34, air is forced to flow into the airflow channel 313 through the second opening 34 and exhausted through the first opening 33 so as to dissipate heat generated from the electronic components on the printed circuit board 36 in accordance with an active heat-dissipating mechanism. Whereas, in another case that the fan 32 is disposed adjacent to the first opening 33, air is forced to flow into the airflow channel 313 through the first opening 33 and exhausted through the second opening 34 so as to dissipate heat generated from the electronic components on the printed circuit board 36 in accordance with an active heat-dissipating mechanism.

In the above embodiments, the first opening 33 and the second opening 34 are disposed in opposite sides of the housing structure 31. Alternatively, the locations of the first opening 33 and the second opening 34 may be varied as long as airflow channel 313 is formed therebetween.

In the above embodiments, the whole surface of the printed circuit board 36 is covered by the protective layer 39. Moreover, the protective layer 39 is uniformly formed on the electronic components 361, the electrical trace patterns and the heat sinks 362. As a consequence, the power converting circuit of the printed circuit board 36 is protected by the protective layer 39. Since the electronic components 361, the electrical trace patterns and the printed circuit board 36 are protected by the protective layer 39, the adverse effects of water, liquid or foreign matters entering the receptacle 38 are minimized. In addition, since the protective layer 39 is attached on the electronic components 361, the heat generated from the electronic components 361 is conducted to the protective layer 39, radiated to the receptacle 38 and dissipated away by the flowing air which is driven by the fan 32. Therefore, the waterproof structure of the present invention is capable of enhancing heat-dissipating efficiency and preventing from moisture attack.

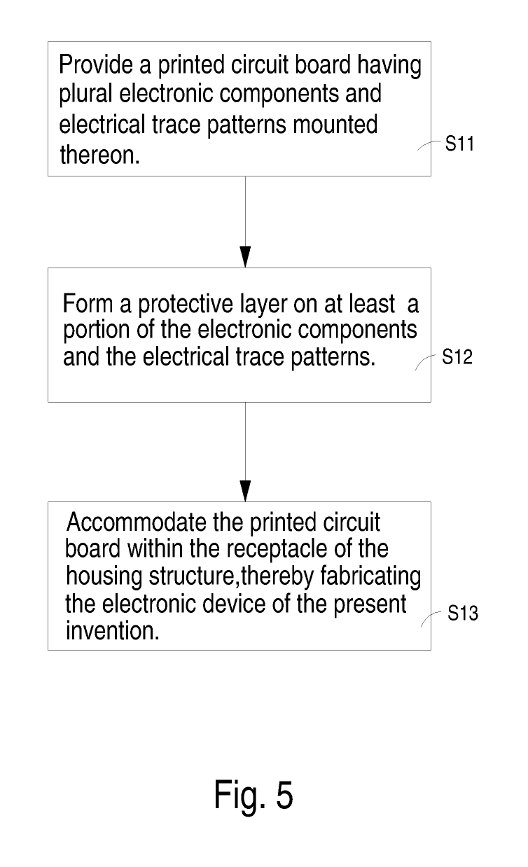

Hereinafter, a process of fabricating an electronic device with a waterproof structure will be illustrated with reference to a flowchart of FIG. 5. First of all, in the step S11, a printed circuit board 36 is provided. Plural electronic components 361 and electrical trace patterns are mounted on the printed circuit board 36 to form a power converting circuit in order to converting an input voltage into a regulated DC output voltage for powering an electronic product. Next, in the step S12, a protective layer 39 is formed on at least a portion of the electronic components 361 and the electrical trace patterns on the printed circuit board 36. Afterwards, in the step S13, the printed circuit board 36 is accommodated within the receptacle 38 of the housing structure 31, thereby fabricating the electronic device 3 of the present invention.

In some embodiments, the protective layer 39 is made of conformal coating material such as polyurethane, poly-para-xylylene (Parylene). The protective layer 39 is formed on the printed circuit board 36 by a dip coating, spin-coating or spraying process. The conformal coating material is applied in a solution or a spray liquid, and then solidified at room temperature or elevated temperature. Optionally, after the conformal coating material is solidified, a baking step is performed to quickly form the protective layer 39. Depending on the type of the conformal coating material, UV irradiation or baking step is used to cure the protective layer 39. The thickness and the color of the protective layer 39 may be selected as required. The printed circuit board 36 may be partially or completely covered by the protective layer 39 so as to protect specified regions of the printed circuit board 36. Moreover, the conformal coating material is optionally filled in the gap between the upper housing 311 and the lower housing 312 of the housing structure 31, thereby increasing the waterproof property of the housing structure 31. The electronic device of the present invention includes but is not limited to a portable electronic device.

From the above description, since a protective layer is formed on at least a portion of the electronic components and the electrical trace patterns on the printed circuit board, the adverse effects of water, liquid or foreign matters entering the receptacle 38 are minimized. Therefore, the waterproof structure of the present invention is capable of enhancing heat-dissipating efficiency and preventing from moisture attack, and thus applicable to most circumstances. In addition, the electronic device of the present invention is fabricated in a simplified and cost-effective manner. Moreover, since the protective layer has additional functions of withstanding vibration, impact or pressure, the electronic device of the present invention has extended life and can be operated in many circumstances.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. An electronic device with a waterproof structure, comprising:
a housing structure including a receptacle, a first opening and a second opening;
a printed circuit board disposed within said receptacle and including plural electronic components and electrical trace patterns thereon; and
a protective layer formed on at least a portion of said electronic components and said electrical trace patterns to protect said printed circuit board from moisture attack.

2. The electronic device according to claim 1 wherein said electronic device is a power adapter or a power supply apparatus.

3. The electronic device according to claim 1 wherein said housing structure includes an upper housing and a lower housing.

4. The electronic device according to claim 1 further including a fan, which is disposed within said housing structure.

5. The electronic device according to claim 4 wherein said fan is a blower or an axial-flow fan.

6. The electronic device according to claim 4 wherein said fan is disposed adjacent to said first opening or said second opening.

7. The electronic device according to claim 1 further including a power input member and a power output member.

8. The electronic device according to claim 1 wherein said protective layer is made of conformal coating material.

9. The electronic device according to claim 8 wherein said protective layer is formed on said printed circuit board by a dip coating, spin-coating or spraying process.

10. A process for fabricating an electronic device with a waterproof structure, said process comprising steps of:
(a) providing a printed circuit board, wherein plural electronic components and electrical trace patterns are mounted on said printed circuit board;
(b) forming a protective layer on at least a portion of said electronic components and said electrical trace patterns, which are mounted on said printed circuit board; and
(c) accommodating said printed circuit board within a receptacle of a housing structure, thereby fabricating said electronic device.

11. The process according to claim 10 wherein said step (b) further includes a step of heating said protective layer.

12. The process according to claim 10 wherein said electronic device is a power adapter or a power supply apparatus.

13. The process according to claim 10 wherein said housing structure includes an upper housing and a lower housing.

14. The process according to claim 10 wherein said housing structure further includes a first opening and a second opening.

15. The process according to claim 10 wherein said step (c) further includes a step of providing at least a fan within said housing structure.

16. The process according to claim 15 wherein said fan is a blower or an axial-flow fan.

17. The process according to claim 15 wherein said fan is disposed adjacent to said first opening or said second opening.

18. The process according to claim 10 wherein said step (c) further includes a step of providing a power input member and a power output member.

19. The process according to claim 10 wherein said protective layer is made of conformal coating material.

20. The process according to claim 19 wherein said protective layer is formed on said printed circuit board by a dip coating, spin-coating or spraying process.
